(19) United States
(12) Patent Application Publication
(10) Pub. No.: US 2005/0031970 A1
(43) Pub. Date: Feb. 10, 2005

(54) Group iia metal fluoride single crystals suitable for below 200 nm optical lithography and a method for selecting such crystals

(76) Inventors: Chong P. An, Painted Post, NY (US); Charlene M. Smith, Corning, NY (US)

Correspondence Address: CORNING INCORPORATED, SP-TI-3-1, CORNING, NY, 14831, US

(21) Appl. No.: 10/900,757

(22) Filed: Jul. 27, 2004

Related U.S. Application Data
(60) Provisional application No. 60/492,539, filed on Aug. 4, 2003.

(51) Int. Cl. G03F 9/00

(52) U.S. Cl. 430/5

(57) ABSTRACT

The invention is directed to a method for determining metal fluoride crystals that are suitable for use in below 200 nm optical lithography by correlation of thermally stimulated current (TSC) measurements to fluence dependent transmission (FDT) measurements; and to metal fluoride crystals suitable for below 200 nm optical lithography, such crystals having a fluent dependent transmission slope that is linearly dependent on the thermally stimulated peak maximum. Crystals suitable for below 200 nm lithography can be determined by using the standard linear relationship between the TSC peak strengths and the FDT slopes without further more FDT measurements.

### CLAIM OF PRIORITY

This application claims the benefit priority of U.S. Provisional Patent Application No. 60/492,539 filed Aug. 4, 2003.

### FIELD OF THE INVENTION

The invention is directed to a method for predicting laser-induced damage caused to single crystals of ionic materials, and in particular to metal fluorides of formula MF₂; using such predictions to identify metal fluoride crystals suitable for use in below 200 nm optical lithography; and metal fluoride crystals suitable for use in below 200 nm optical lithography.

### BACKGROUND OF THE INVENTION

Calcium fluoride (CaF₂) single crystals have been expected to be the material of choice for the optics of next-generation photolithography techniques in use by the semiconductor industry. These lithographic systems will involve the use of high power lasers operating at vacuum ultraviolet (“VUV”) wavelengths below 200 nm, typically at 193 nm and 157 nm. However, one of difficulties involved in operating at these low wavelengths is that the damage that the laser can cause to the CaF₂ single crystals that will be used in the optics. This damage results in a decrease in the optical transmission under ultraviolet (UV) laser irradiation. Since the photolithography technique requires very high optical transmission, the reduction of laser damage effect is an important part of product quality in the manufacturing of CaF₂ crystals. The laser damage effect is measured in a Fluence Dependent Transmission (“FDT”) test by monitoring the transmission change under a series of UV excimer laser pulses. The typical behavior of CaF₂ in FDT test has been found to have two aspects. The first is the “transmission decay speed”; that is the time required to reach the saturation with a fixed laser pulse energy. The second is “FDT slope”; that is, the linear dependence of the optical transmission at saturation under laser pulse energy variation. With regard to the decay speed, it has been found that CaF₂ crystals can be sorted into two broad groups. One group of CaF₂ products, single crystals and optical elements made therefrom, was found to have a fast decay behavior; for example, <10 seconds up to transmission saturation under 1 -50 mJ/cm² per a pulse and 100 pulses per a second. The second group has a slow decay; for example, >100 second up to saturation. It has also been found that the FDT slope does not correlate with the decay speed. Moreover, the FDT slope is not a constant for CaF₂ crystals with very low impurities (for example, impurities determined by optical absorption spectroscopy). With respect to the laser damage inflicted on crystals, the main problems are to identify the origins of the FDT behaviors (decay speed and slope) and to develop a method for quantification of the origins.

The radiation damage effect of CaF₂ crystals by X-ray or electron-beam irradiation has been investigated over several decades. High energy irradiation (for example, X-ray, electron-beam, and short wavelength UV light) has been reported to produce F-centers which are free electrons trapped into a fluorine anion vacancy. The F-centers in CaF₂ have strong optical absorption at 385 nm with a very broad width. In addition, the aggregation centers of F-centers with themselves and/or other impurities have optical absorption in UV spectral range. The optical absorption of the radiation-induced defects is considered as the origin of the transmission decreases observed in CaF₂ crystals. However, what has not been clearly identified are the factors (impurities, defects, etc) that cause the FDT behaviors.

The measurement techniques use to characterize defects in CaF₂ crystals are based on the optical spectroscopy (absorption and emission measurements) and magnetic resonance (NMR, EPR and similar techniques). In addition to these well-known methods, a method called the “thermally stimulated current” (“TSC”) technique was developed in the 1960's to characterize the defects of electric charges or dipoles in ionic crystals. [See C. Bucci and R. Fieschi, Physical Review Letters 12: 16 (1964)]. TSC method was reported to characterize the point structural defects (vacancies and interstitials) in CaF₂. [See I. Kunze et al., Physica Status Solidi (A) 13: 197 (1972) and K. Tanaka et al, J. Physics and Chemistry of Solids 57: 307 (1996).] However, no investigations have been done to determine if there is any correlation between the FDT behaviors and the TSC results. Consequently, there is a need to find a method of correlating FDT behaviors and TSC results in order to aid in the determination of what crystals are suitable for less than 200 nm lithographic methods.

### SUMMARY OF THE INVENTION

The present invention is directed to a method of correlating TSC measurement results with FDT behaviors. In particular, the invention is directed to a method of correlating TSC measurement results with FDT behaviors in order to provide a means for which determining metal fluoride crystals, and optical elements made therefrom, are suitable for use in optical lithography systems; for example, lithography systems operating below 200 nm. The metal fluoride crystals are Group IIA metal fluorides of formula MF₂ where M is Ca, Mg, Ba and Sr (including mixtures thereof). Crystals of formula MF₂ are suitable for below 250 nm lithographic applications and particularly for below 200 m lithography; for example, at 193 and 157 nm. The invention can also be used to diagnose and select alkali metal single crystals of formula M° F., where M′ is Li and K, suitable for use in systems requiring such crystals. Use of the method of the invention avoids excessive costs and time in manufacturing of metal fluoride single crystals suitable for optical lithography.

The present invention is also directed to metal fluoride single crystals suitable for use in below 200 nm optical lithographic processes, said crystals having a FDT slope that is linearly dependent on the TSC peak maximum. Such crystals are of formula MF₂ and the metal is selected from the group consisting of calcium, barium, magnesium and strontium, or mixtures thereof. Such crystals have a TSC peak at 305° K. of 10⁻¹² ampere or greater.

### BRIEF DESCRIPTION OF THE DRAWINGS

FIG. 1A illustrates the basic principles of the thermally stimulated current (“TSC”) method of characterizing the defects of electric charges or dipoles in ionic crystals.

FIG. 1B illustrates the TSC peaks that appears when two kinds of frozen defects are depolarized at their own temperatures by thermal activation, respectively.

FIG. 2 Illustrates typical TSC spectra for CaF₂ crystals exhibiting fast decay (upper curve) and slow decay (lower curve) behaviors in Fluence Dependent Transmission (FDT) tests.

FIG. 3 illustrates the linear relationship between FDT slope and the TSC peak for a high purity CaF₂ single crystals with fast decay behavior in FDT.

### DETAILED DESCRIPTION OF THE INVENTION

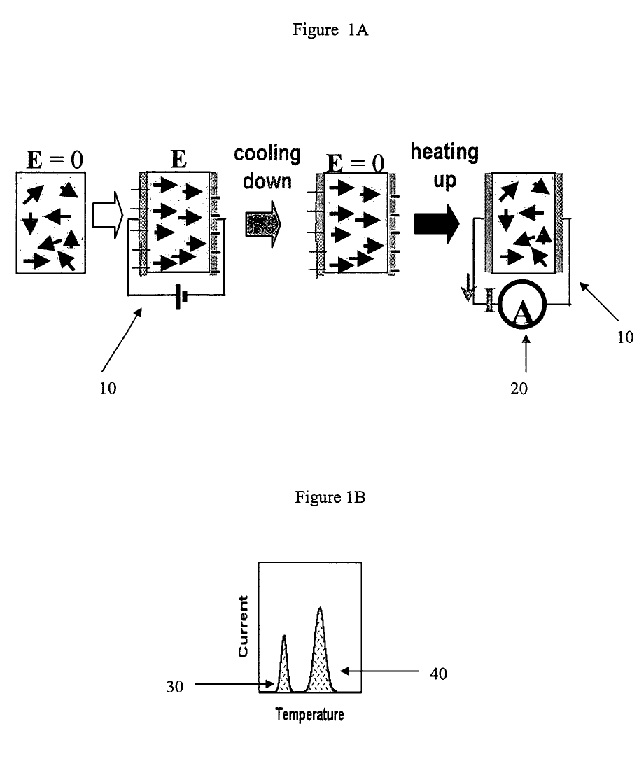

A thermally stimulated current (TSC) method had been developed for analyzing ionic crystals. Referring to FIG. 1A, an electric field is applied on a sample at a selected temperature (for example, Tₚ=30° C.) to polarize electrically charged defects in crystals. Other electric field Ep can be used, but the TSC peak strength varies linearly with Eₚ and exp(1Eₐ/kTₚ) where Eₐ is a thermal activation energy of measuring defects. The electrical polarization is frozen by cooling the sample and the applied field is removed at a low temperature, typically below 100° K.; for example, cooling to liquid nitrogen temperature (78° K.). Subsequently, an electric current from one electrode to the other is monitored while the sample is heated at a constant rate (for example 7° K/minute). The constant rate of heating is typically in the range of 3 to 20° K./minute. When a frozen defect is depolarized at its own particular temperature by thermal activation, a TSC peak appears in the measured electric current spectrum as a function of temperature. The peak strength measured with a same T_{P2} Eₚ and heating rate implies the concentration and electric charge (or dipole moment) of the defects, whereas the peak position on the temperature scales indicates the activation energy of the defect displacement or reorientation of dipole moment. TSC measurements can be used to identify an electrically charged defect in an ionic crystal and to quantify its concentration and thermal properties. FIG. 1B illustrates the current vs. temperature graph for a metal fluoride single crystal sample when one defect is frozen as at numeral 30 and the other is as at numeral 40

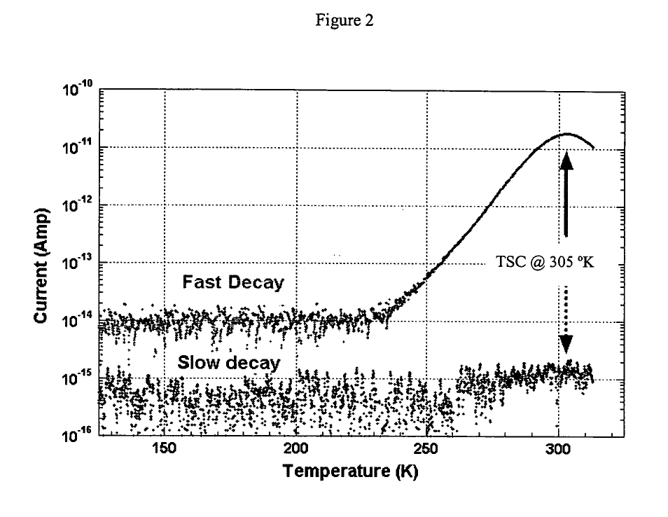

FIG. 2 illustrates two typical thermally stimulated (TSC) spectra. The upper curve is a fast decay sample in FDT which has a very strong TCS peak of approximately 10⁻¹¹ amp (ampere) at 305° K. The lower curve is a slow decay sample which has a very weak TSC peak of approximately 10⁻¹⁵ amp at 305° K. The former correlates to the fast decay in FDT test of CaF₂ crystals whereas the latter correlates to slow decay crystals. Fast decay samples have a TSC peak of than 10⁻¹² amp or greater with a Tₚ+30° C., Eₚ=300V/mm and heating rate=7° K./minute, and slow decay samples have a TCS peak of 10⁻¹⁴ amp or less with the ame TSC conditions. In FIG. 2, the TSC peak at 305° K. was identified to be mobile anion vacancies (not restricted by other defects or impurities) in a CaF₂ crystal. These vacancies are effectively positive-charged. Consequently, the TSC peak strength is related to the concentration of mobile anion vacancies in CaF₂ crystals.

The laser damage effect to CaF₂ crystals under UV irradiation (for example at 193 or 157 μm) is initiated by an incident photon ionizing a host ion to produce a pair of free electron and hole. When a free electron meets with an anion vacancy, the electron is trapped in the anion vacancy and an F-center is formed. Such F-centers have an optical absorption at 385 nm with a very wide bandwidth. F-centers are subsequently aggregated with themselves and with defects/impurities, and the aggregated centers have optical absorption in UV and visible spectral region. While not intending to limited by theory it is suspected that formation of such color centers is related to the Fluence Dependent Transmission (FDT) behaviors at 193 or 157 nm. Fluence Dependent Transmission behavior of a crystal can be determined by subjecting a crystal to a selected wavelength (for example, 193 or 157 nm, or other wavelength depending on the intended application) and varying the fluence levels between selected values. For example, using a laser producing a 193 nm beam, the fluence may be varied between 0.8 and 50 mJ/cm²/pulse, or other selected range. Transmission of the part of the laser exposure wavelength is monitored during exposure. Over the course of exposure the fluence is changes. This change in fluence yields a change in transmission. The transmission reaches a “steady state” value that is plotted in absorption (base 10) units vs. exposure fluence. The slope of the absorption vs. fluence plot is the metric of interest.

The process of laser-induced color center formation which produces FDT behaviors is not fully understood at this time. However, it is believed that at the beginning of this process host anion vacancies play a very important role in producing F-centers with laser-induced free electrons. Consequently, it is necessary to know or to be able to determine the concentration and thermal properties of host anion vacancies in order to predict or estimate FDT results.

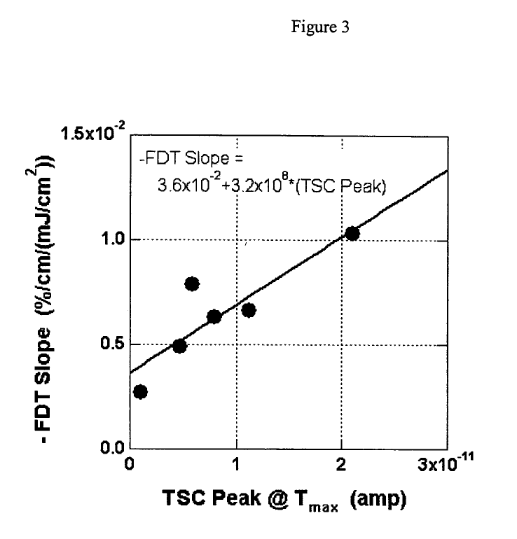

In making a TSC/FDT correlation, only the TSC peak maximum at 305K (=32° C.) is used to make a correlation to FDT results. FIGS. 2 and 3 illustrates the results obtaining using high purity CaF₂ samples manufactured in Corning Specialty Materials. The first achievement is the correlation between the FDT decay speed and the TSC peak strength. The fast decay samples have a very strong TSC peak maximum of over 10⁻¹² amp, whereas the slow decay samples have very weak TSC peak below 10⁻¹⁴ amp [see FIG. 2] The second achievement is the correlation to the FDT slope for highly pure CaF₂ samples which have no UV absorptions due to impurities. As FIG. 3 illustrates, the FDT slope is dependent linearly on the TSC peak maximum. As a result of the correlation between the FDT slope and the TSC peak, one is able to predict whether a particular CaF₂ crystal will be suitable for use in optical lithography methods operating at below 200 nm wavelengths.

The present invention is directed to a method of correlating TSC measurement results with FDT behaviors. In particular, the invention is directed to a method of correlating TSC measurement results with FDT behaviors in order to provide a means for which determining metal fluoride crystals, and optical elements made therefrom, are suitable for use in optical lithography systems; for example, lithography systems operating below 200 nm. The metal fluoride crystals are of general formulas MF₂ and M° F., where M is Ca, Mg, Ba and Sr, and where M′ is Li and K.

The invention thus enables one to select a metal fluoride single crystals suitable for use in below 200 nm optical lithographic processes by measuring only the TSC peak strength of the selected single crystal sample and using the standard linear relationship between the TSC peak strengths and the FDT slopes. Such crystals are of formula MF₂ and the metal is selected from the group consisting of calcium, barium, magnesium and strontium, or mixtures thereof. Such crystals have a TSC peak at 305° K. of 10⁻¹² ampere or greater.

The present invention has been described in general and in detail by way of examples. Persons skilled in the art understand that the invention is not limited necessarily to the specific embodiments disclosed. Modifications and variations may be made without departing from the scope of the invention as defined by the following claims or their equivalents, including equivalent components presently known, or to be developed, which may be used within the scope of the present invention. Hence, unless changes otherwise depart from the scope of the invention, the changes should be construed as being included herein.

1. A metal fluoride single crystal suitable for use in below 200 nm optical lithographic processes, said crystal having a fluence dependent transmission slope that is linearly dependent on the thermally stimulated current peak maximum.

2. The metal fluoride crystal according to claim 1, wherein the metal fluoride is of formula MF₂ and the metal is selected from the group consisting of calcium, barium, magnesium and strontium, or mixtures thereof.

3. The metal fluoride crystal according to claim 1, wherein the metal is calcium.

4. The metal fluoride crystal according to claim 1, wherein said crystal has a TSC peak at 305° K. of 10⁻¹² ampere or greater.

5. The metal fluoride crystal according to claim 2, wherein said crystal has a TSC peak at 305° K. of 10⁻¹² ampere or greater.

6. The metal fluoride crystal according to claim 3, wherein said crystal has a TSC peak at 305° K. of 10⁻¹² ampere or greater.

7. A method of identifying metal fluoride crystals suitable for use in below 200 nm optical lithography, said method comprising the steps of:
selecting a standard set of high purity metal fluoride single crystals;
determining the fluence dependent transmission of the metal fluoride crystals;
determining the peak strength of the metal fluoride crystals using thermally stimulated current measurements;
plotting the fluence dependent transmission measurements against the thermally stimulated peak strength for the metal fluoride crystals;
finding a linear relationship between the fluence dependent transmission slope and the thermally stimulated peak strength; and
measuring the thermally stimulated current peak strength of a under-testing metal fluoride single crystal;
wherein crystals suitable for below 200 nm lithography can be determined by using the standard linear relationship between the thermally stimulated current peak strengths and the fluence dependent transmission sloops.

8. A method of identifying metal fluoride crystals suitable for use in below 200 nm optical lithography, said method comprising the steps of:
(a) selecting a standard set of high purity metal fluoride crystals;
(b) determining the peak strength of the metal fluoride crystals using thermally stimulated current measurements by:
applying an electric field to a metal fluoride crystal at a selected temperature to polarize electrically charged defects in the crystal;
cooling the crystal to a selected temperature below 100° K.;
removing the applied electric field while the crystal is at low temperature;
heating the crystal at a constant rate while measuring the current through the crystal using a pair of electrodes
(c) determining the fluence dependent transmission of the metal fluoride crystasl;
(d) plotting the fluence dependent transmission measurements against the thermally stimulated peak temperature for a metal fluoride crystal;
(e) finding a linear relationship between the fluence dependent transmission slopes and the thermally stimulated current peak strengths; and
(f) measuring only the thermally stimulated current peak strength of a under-testing metal fluoride single crystal sample;
wherein crystals suitable for below 200 nm lithography can be determined by using the standard linear relationship between the thermally stimulated current peak strengths and the fluence dependent transmission slopes.

9. The method according to claim 8, wherein the cooled sample is heated at a constant rate in the range of 3 to 30° C./minute.

10. The method according to claim 7, wherein the metal fluoride single crystal is selected from the group consisting single crystals of barium fluoride, magnesium fluoride and strontium fluoride, and crystals containing mixtures of said metals.

11. The method according to claim 8, wherein the metal fluoride single crystal is selected from the group consisting single crystals of barium fluoride, magnesium fluoride and strontium fluoride, and crystals containing mixtures of said metals.

12. The method according to claim 9, wherein the metal fluoride single crystal is selected from the group consisting single crystals of barium fluoride, magnesium fluoride and strontium fluoride, and crystals containing mixtures of said metals.

13. The method according to claim 7, wherein the metal fluoride single crystal is calcium fluoride.

14. The method according to claim 8, wherein the metal fluoride single crystal is calcium fluoride

15. The method according to claim 9, wherein the metal fluoride single crystal is calcium fluoride
